(19) United States
(12) Patent Application Publication
(10) Pub. No.: US 2025/0322985 A1
(43) Pub. Date: Oct. 16, 2025

(54) MULTI-SUBSTRATE TRANSFORMER PACKAGES WITH MAGNETOSTRICTION MANAGEMENT

(71) Applicant: Allegro MicroSystems, LLC, Manchester, NH (US)

(72) Inventors: Manoj Balakrishnan, Ingleby Barwick (GB); Paul A. David, Bow, NH (US); Andrew Thompson, Cheshire (GB)

(73) Assignee: Allegro MicroSystems, LLC, Manchester, NH (US)

(21) Appl. No.: 18/633,685

(22) Filed: Apr. 12, 2024

(51) Int. Cl. H01F 27/28; H01F 27/24; H01L 21/48; H01L 23/538; H01L 23/64

(52) U.S. Cl. CPC H01F 27/2804; H01F 27/24; H01L 21/4853; H01L 23/5386; H01L 23/645

(57) ABSTRACT

Isolation transformer packages and structures and related methods reduce or minimize deleterious effects arising from magnetostriction during operation of the included transformer. An example transformer based integrated circuit package includes first and second substrates that include a space for receiving a magnetic core and that are joined together. A magnetic core is disposed in the space defined by the substrates, with the magnetic core including a soft ferromagnetic material. The space between surfaces of the substrates and an exterior surface of the magnetic core allows the magnetic core to expand and contract during operation. Pluralities of conductive traces of both substrates, having first and second galvanically separate groups, form first and second transformer coils disposed about the magnetic core. An injection port can be disposed in the first or second substrate to allow injection of underfill into one or more regions between the first substrate and the second substrate.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

Aspects of the present disclosure are directed to isolation transformer structures and packages having magnetostriction management structures and related methods.

One general aspect of the present disclosure includes a transformer-based integrated circuit (IC) package. The transformer-based integrated circuit can include: a magnetic core including a soft ferromagnetic material; a first substrate having a first plurality of conductive traces including first and second galvanically separate groups, where the first substrate includes a first receiving surface configured to receive the magnetic core; and a second substrate having a second plurality of conductive traces including first and second galvanically separate groups, where the second substrate includes a second receiving surface configured to receive the magnetic core; where the first and second galvanically separate groups of the first plurality of conductive traces is connected to (or can be configured for connection to) the first and second galvanically separate groups of the second plurality of conductive traces at a plurality of connections, forming first and second coils galvanically separate coils disposed about the magnetic core, where the first and second coils and magnetic core are configured as a transformer.

Implementations may include one or more of the following features. The IC package may include an encapsulant configured to encapsulate the first substrate, where the encapsulant defines one or more surfaces of a package body. The first receiving surface and second receiving surface can provide a space between the first and second substrates and an exterior surface of the magnetic core. The space may include a gap between about 250 nm to about 2 mm, in some embodiments; such a gap may have other dimensions in other embodiments. The IC package may include at least one semiconductor die (a.k.a., IC die) disposed on the first substrate and/or second substrate. The at least one semiconductor die may include an integrated circuit (IC). The IC may include a gate driver. The first and second coils may be configured as primary and secondary coils in a step-up configuration, e.g., where the gate driver is connected to the secondary coil. The magnetic core may include ferrite. The first substrate and/or second substrate may include a printed circuit board (PCB). The first substrate and/or second substrate may include a glass substrate. The first substrate and/or second substrate may include a ceramic substrate. The IC package may include underfill material disposed between the first substrate and second substrate. The IC package may include an injection port disposed in the first or second substrate and configured to allow injection of underfill into one or more regions between the first substrate and the second substrate. The underfill may include encapsulation material. The underfill may include epoxy, in some embodiments, though other materials may be used in other embodiments.

Another general aspect of the present disclosure includes a method of making an integrated circuit (IC) and transformer package. The method can include: providing a magnetic core including soft ferromagnetic material; providing a first substrate having a first plurality of conductive traces including first and second galvanically separate groups, where the first substrate includes a first receiving surface for receiving a first portion of the magnetic core; providing a second substrate having a second plurality of conductive traces including first and second galvanically separate groups, where the second substrate includes a second surface for receiving a second portion of the magnetic core; positioning the magnetic core between the first and second receiving surfaces; and joining the first plurality of conductive traces with the second plurality of conductive traces, thereby forming primary and secondary transformer coils configured about the magnetic core.

Implementations may include one or more of the following features. The method may include providing one or more IC die to the first or second substrate, where the one or more IC die is/are connected to at least a subset of the first plurality of conductive traces or second plurality of conductive traces. The method may include providing an encapsulant to the first or second substrates, the encapsulant defining one or more surfaces of a package body. The first receiving surface and second receiving surface may provide a space between the first and second substrates and an exterior surface of the magnetic core. The method may include providing at least one semiconductor die disposed on the first substrate and/or second substrate. The at least one semiconductor die may include an integrated circuit (IC). The IC may include a gate driver. Primary and secondary coils can be configured in a step-up configuration, in some embodiments; other embodiments may have different configurations, e.g., a step-up configuration, a power transformer configuration, etc. The magnetic core may include ferrite. The first substrate and/or second substrate may include a printed circuit board (PCB). The first substrate and/or second substrate may include a glass substrate. The first substrate and/or second substrate may include a ceramic substrate. The method may include providing underfill material disposed between the first substrate and second substrate. The method may include providing an injection port disposed in the first or second substrate and configured to allow injection of underfill into a region between the first substrate and second substrate.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1A shows a cross sectional view of an example multi-substrate isolation transformer package with magnetostriction management structure, in accordance with the present disclosure;

FIG. 1B shows a cross sectional view of a package including the package of FIG. 1A with added insulator material, in accordance with the present disclosure;

FIG. 1C shows a cross-sectional view of a package including the package of FIG. 1B with an added injection port for application of insulator material, in accordance with another embodiment of the present disclosure; and

FIG. 2 is a diagram showing an example method of fabricating a multi-substrate isolation transformer package with magnetostriction management structure, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformers and transformer structures that can be used for galvanic isolation (a.k.a., voltage isolation). Embodiments and examples can include multi-substrate packages with isolation-transformer structures having a core and coils in a transformer configuration and providing galvanic isolation for, e.g., integrated circuits (ICs) or other components/circuits. Such ICs may be in (packaged or unpackaged) die included in the multi-substrate package or outside of and connected to the multi-substrate package. In some embodiments, an isolation transformer of a package may have, e.g., a step up, a step down, or a power transformer configuration. Signals and/or power may be transferred from the primary side of the isolation transformer to the secondary side.

As previously noted, one or more (e.g., first and second) semiconductor die having one or more integrated circuits (a.k.a., “IC die”) can be included in transformer packages in accordance with the present disclosure. Such integrated circuits can include, e.g., but are not limited to, high-voltage circuits such as gate drivers configured to drive an external gate on a solid-state switch, e.g., a field effect transistor (FET), a metal oxide semiconductor FET (MOSFET), a metal semiconductor FET (MESFET), a gallium nitride FET (GaN FET), a high electron mobility transistor (HEMT), a silicon carbide FET (SIC FET), an insulated gate bipolar transistor (IGBT), or another load. The included transformer structure provides galvanic separation between the primary and secondary transformers sides, including any connected ICs.

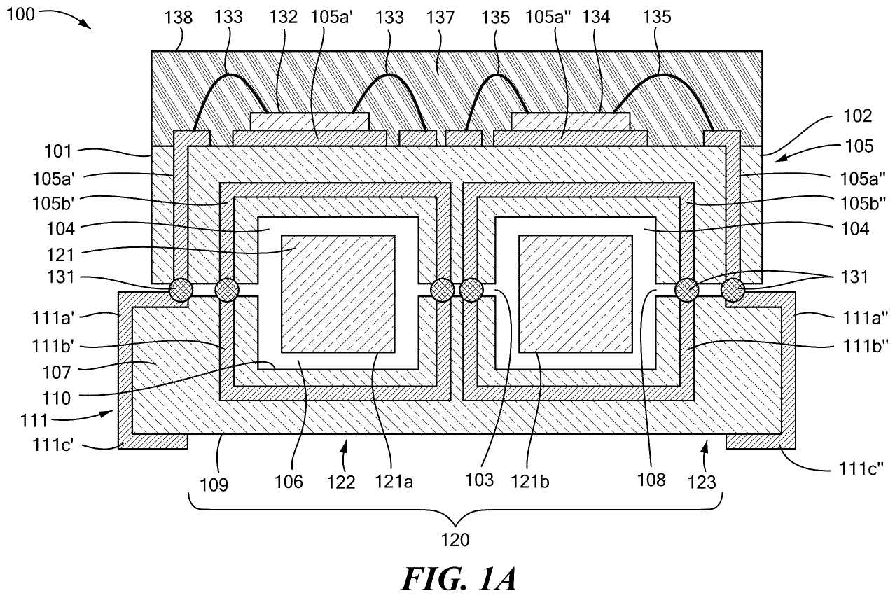

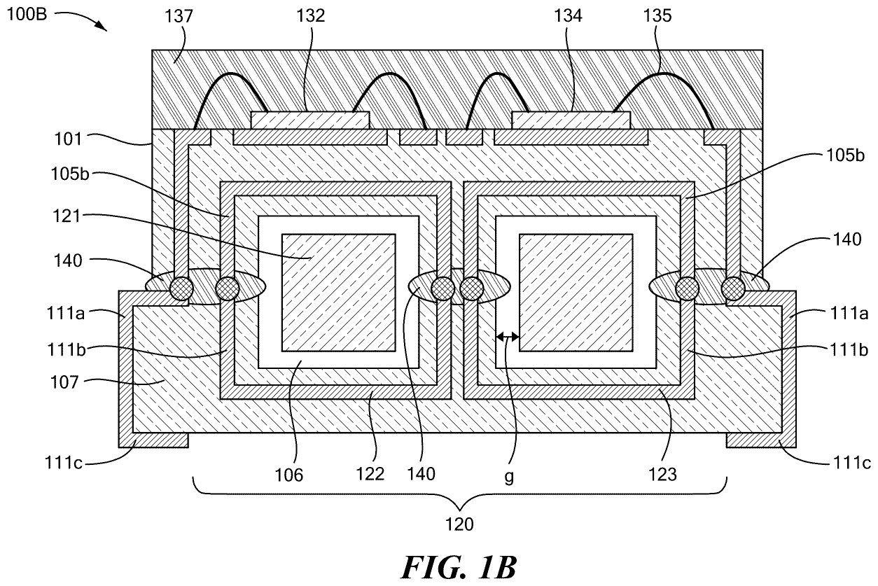

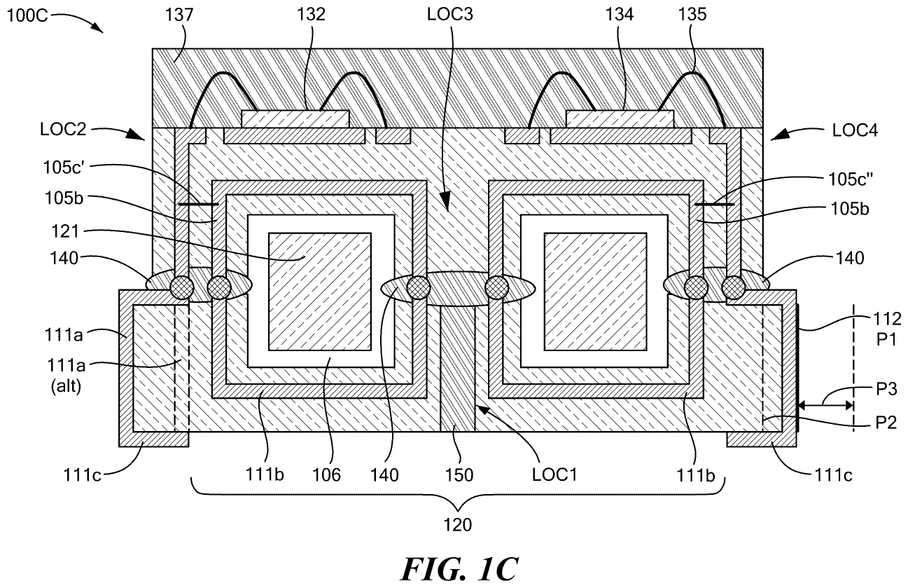

FIG. 1A shows a cross sectional view of an example multi-substrate isolation transformer package 100A with magnetostriction management structure, in accordance with the present disclosure. Package 100A includes first substrate 101, second substrate 107, and transformer 120 having magnetic core 121, and first and second galvanically separate coils 122, 123 that are each formed by coil portions residing in the first and second substrates 101, 107, as explained in further detail below. Magnetic core 121 is shown with cross-sections 121a-b. In some embodiments, magnetic core may have a closed shape, e.g., a toroidal or rectangular shape.

First substrate 101 includes a pair of opposed (first and second) sides 102, 103 and a receiving surface (first receiving surface) 105 configured to receive a magnetic core 121 of transformer 120, as described in further detail below. First substrate 101 can include a plurality of conductive structures 105 (e.g., conductive traces, vias, posts, etc.), including groups that are galvanically separate, corresponding and connected to primary and secondary sides of transformer 120. Major galvanically separate features of package 100A are indicated by prime, ′, and double-prime, ″, notations in FIG. 1A; while the features are still galvanically separate those notations are generally omitted from FIGS. 1B-1C for improved visual clarity. The plurality of conductive structures 105 can include connection structures 105a (e.g., interconnect traces, die pads, etc.) and coil portions 105b (with galvanically separate portions indicated as 105b′ and 105b″).

Second substrate 107 has a pair of opposed (first and second) sides 108, 109 and a receiving surface (second receiving surface 110) configured to receive magnetic core 121. Second substrate 107 can include plurality of conductive structures 111 (e.g., conductive traces, vias, posts, etc.) including groups that are galvanically separate, corresponding and connected to primary and secondary sides of transformer 120. As noted above, galvanically separate features of package 100A are generally indicated by prime, ′, and double-prime, ″, notations; those notations are generally omitted from FIGS. 1B-1C for improved visual clarity. The plurality of conductive structures 111 can include connection structures for external and/or internal connections 111a (e.g., wettable flanks), coil portions 111b (with galvanically separate portions indicated as 111b′, 111b″).

Transformer 120 includes first (primary) and second (secondary) coils 122, 123 formed from coil portions 105b′, 105b″ of first substrate 101 and the coil portions 111b′, 111b″ of second substrate 107. It will be understood that, while coils 122 and 123 are each represented by a single winding shown in the drawings, each coil will have one or more windings, e.g., each coil may include a plurality of coil windings having a pitch between adjacent winding and extending into and/or out of the plane of the drawings. Coils 122 and 123 may each have a desired number of windings. Transformer 120 may be configured as a step-up transformer, a step-down transformer, or a power transformer, in respective embodiments.

The receiving surfaces 104 and 110 of substrates 101 and 107 are configured to receive and (loosely) hold magnetic core 121, providing a space 106 (a.k.a., recess, depression, aperture, or cavity) that can accommodate the core 121 (e.g., with toroidal or rectangular shape) and expansion of the core 121 due to magnetostriction and/or heating during operation of transformer 120. While substrate 101 and substrate 107 are each shown as contributing approximately 50% of one dimension (e.g., height) of space 106, the proportion contributed by each substrate may vary in other embodiments, e.g., over the range of 0-100%.

Space 106 can provide a desired gap (e.g., “g” in FIG. 1B) between a surface of a substrate (105 and/or 107) and core 121 (before or after expansion due to heating or magnetostriction). In some embodiments such gap may be included in a range of between about 250 nm to about 2 mm, inclusive of the end-range values; the gap may have other values in other embodiments. In some embodiments, the gap may be uniform around the core 121 (e.g., relative to a nominal, unexpanded core shape or relative to a core that has one or more dimensions expanded or shrunk due to operation and/or heating). In other embodiments, the gap may be non-uniform.

One or more semiconductor die, e.g., die 132 and 134 as shown, can be disposed on substrate 101 and/or substrate 107. Die 132, 134 may be connected by suitable connections, e.g., as shown by wire bonds 133, 135, respectively, to conductive interconnect structures 104a. In some embodiments, IC die 132 and/or 134 may be packaged die. In some embodiments, IC die 132 and/or 134 may be unpackaged die. For embodiments where multiple die are present, one or more die may be connected to each galvanically separate side (e.g., primary or secondary) of transformer 120 such that at least some (two or more) of the multiple (plurality of) die are galvanically separated. In some embodiments, die 132 and/or 134 may be flip-chip or wire-bonded to a receiving surface or surfaces of a substrate. In some embodiments, IC die 132 and/or 134 can include quad flat no-lead (QFN) packages. In some embodiments, die 132 and/or 134 may be protected (encapsulated) with compression molding or other suitable encapsulant(s), e.g., epoxy “glop-top” coating, etc.

In some embodiments, substrate 101 and/or substrate 107 may include a printed circuit board (PCB), e.g., a PCB including FR4, FR5, or other PCB material(s). In some embodiments, substrate 101 and/or substrate 107 may include one or more layers of low-temperature cofired ceramic (LTCC) or high-temperature cofired ceramic (HTCC). In some embodiments, substrate 101 and or substrate 107 may include an alumina substrate or a glass substrate comprising one or more layers of metal and insulation.

Transformer core 121—shown with cross-sections 121a and 121b—can include one or more soft (referring to magnetic property) ferromagnetic materials. In some embodiments, core 121 can include ferrite, iron particles, ferrosilicon, nickel, nickel alloys (e.g., iron nickel), and/or the like. In some embodiments, core 121 can include a sintered soft ferromagnetic material. Insulating material (not shown) may be disposed between core 121 and substrate 101 and/or substrate 107, e.g., at one or more regions or locations within space 106. Coils 122 and 123 can be connected, e.g., by way of conductive galvanically separate structures/traces (e.g., included in galvanically separate groups of conductive traces 105a), respectively, to die 132 and 134. Coils 122 and 123 can be connected, e.g., by way of galvanically separate conductive structures/traces 105a and/or 111, to respective sets of connection structures for connection to structure(s), systems, and/or circuits outside of package 100A, e.g., as shown by wettable flanks 111a and/or solder contacts or pads 111c.

FIG. 1B show a cross sectional view of package 100B including package 100A of FIG. 1A along with added insulator material, in accordance with the present disclosure. As shown, in some embodiments, insulator (dielectric) material 140 can be applied (disposed) between adjoining surfaces of the first and second substrates 101 and 107. For example, insulator material 140 may be applied at one or more locations (three are shown) between surface 103 of substrate 101 and surface 108 of substrate 107. Any suitable insulator material may be used. Such insulator material 140 may serve to improve electrical isolation of structures, components, and/or elements on the primary and secondary sides of transformer 120—and may facilitate obtaining a desired or nominal creepage rating. In some embodiments, underfill (e.g., epoxy) may be used as insulator material 140.

FIG. 1C show a cross sectional view of package 100C including package 100B of FIG. 1C with an added injection port 150 for injection of insulator material 140, in accordance with the present disclosure. In some embodiments, injection port 150 can be configured to receive a liquid or gel insulator material and convey the material (e.g., under pressure) to one or more locations between adjoining surfaces of the first and second substrates 101 and 107.

While injection port 150 is shown at a location on substrate 107 between coils 122 and 123, one or more similar injection ports may be positioned/disposed at other locations for a package within the scope of the present disclosure. Example alternate positions for injection port 150 are indicated at LOC2, LOC3, and LOC4; other positions may of course be used for an injection port 150 beyond those indicated in the drawing. Some positions, e.g., LOC2 and LOC4 at the edges of package 100C, for an injection port may be particularly useful when fabricating multiple packages from relatively large substrate structures and prior to “singulation” of the individual packages. In some embodiments, a wettable flank may be omitted, e.g., as indicated by via 111a (alt).

FIG. 1C also shows representative connections 105c (e.g., galvanically separate conductive traces 105c′ and 105c″) connecting coils 122 and 123 to die 132 and 134, respectively. It will be understood that those connections are shown as an example, and other suitable connections may be used between the coils 122, 123 and die 132, 134. FIG. 1C further shows that side surfaces (sidewalls) of substrates 101 and 107 are not required to be colinear; in other words, the substrates may have different widths relative to one another. For example, while sidewall 112 is shown at position P1, in other embodiments it may be located at other positions, e.g., P2 or P3, etc. In some examples, a package (e.g., 100A, 100B, ad/or 100C), may have a relatively small footprint, as a result of the structure shown and described, e.g., of or about 156 mm² or less.

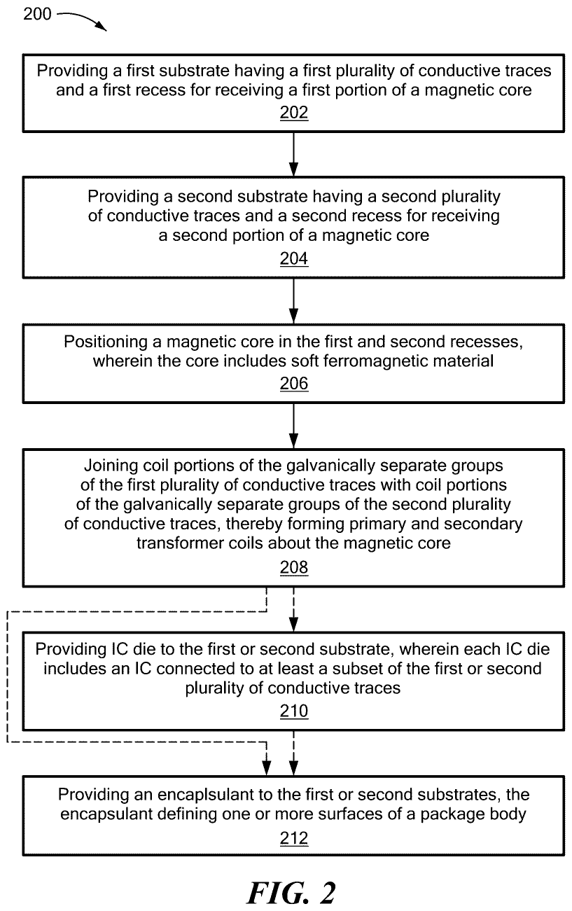

FIG. 2 is a diagram showing an example method 200 of fabricating an isolation transformer package with magnetostriction management structure, in accordance with the present disclosure. Method 200 can include providing a first substrate having a first plurality of conductive traces, including first and second galvanically separate groups, and a first recess (space, cavity, depression, aperture) for receiving a first portion of a magnetic core, as described at 202. A second substrate having a second plurality of conductive traces, including first and second galvanically separate groups, and a second recess (space, cavity, depression, aperture) for receiving a second portion of a magnetic core can be provided, as described at 204. A magnetic core can be positioned in the first and second recesses, wherein the core includes soft ferromagnetic material, as described at 206. The core can be loosely held within the space so as to be contained within the space while allowing expansion of the core due to magnetostriction and/or heating during operation. Coil portions of the galvanically separate first and second groups of the first plurality of conductive traces can be joined with coil portions of the galvanically separate first and second groups of the second plurality of conductive traces, thereby forming primary and secondary transformer coils configured about the magnetic core, as described at 208.

As an optional step, one or more (e.g., two) IC die may be provided to the first or second substrate, wherein each IC die includes an IC connected to at least a subset of the first or second plurality of conductive traces, as described at 210. As an optional step, an encapsulant (e.g., compression molding) may be provided to the first or second substrates, the encapsulant can define (e.g., after molding) one or more surfaces of a package body, as described at 212. Encapsulant may be provided to the first or second substrates without IC die being present in some embodiments, or encapsulant may be provided after one or more IC die have been provided for a package, as indicated.

In some examples and/or embodiments, integrated circuits (ICs), e.g., in IC die 132 and 134 in FIGS. 1A-1C, or other conductive features of the primary and secondary sides of a transformer structure in a transformer-containing package according to the present disclosure can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides, e.g., a distance between die, or a distance between exposed leads connected to the die, may be, may be approximately, or may be at least 1.2 mm, 1.4 mm, 1.5 mm, 3.0 mm, 4.0 mm, 5.5 mm, 7.2 mm, 8.0 mm, 10 mm, or 10+mm in respective examples. Such a distance between conductive portions or areas of die can include any insulation covering a conductor, e.g., such as plastic coating of a wire/lead. Other distances between conductive parts, components, and/or features of an IC/transformer package may also be designed and implemented, e.g., to meet desired internal creepage, voltage breakdown, or external clearance requirements, e.g., between external leads.

In some examples and embodiments, a dielectric material (e.g., gel) may be used for potting and/or protecting substrates, assemblies, and/or packages, including isolation transformer co/or die and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”), and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power, current. or voltage rating. Embodiments and examples of the present disclosure can enable or facilitate lower costs and higher scalability for manufacturing of IC packages/modules having voltage-isolated IC die and (galvanic isolation) transformers. Embodiments and examples of the present disclosure can enable or facilitate simpler and less expensive manufacturing, including placement of the integrated/embedded transformer. Embodiments and examples of the present disclosure can enable or facilitate a smaller footprint size compared to prior techniques. Embodiments and examples of the present disclosure can be made without requiring wire bonds for magnetic core (e.g., ferrite) windings, since magnetic core windings are provided using conductive structure (e.g., copper tracks) in package substrates. Embodiments and examples of the present disclosure can enable or facilitate low parasitic DC resistance for primary and secondary coils made via conductive structures in substrates (e.g., PCB copper tracks). Embodiments and examples of the present disclosure can enable or facilitate reduction or elimination of magnetostriction during operation of the embedded magnetic core as the receiving space of the magnetic core may be devoid of material (e.g., mold compound, underfill, etc.) and provide loose holding/containment of the magnetic core.

Various embodiments and/or examples of the concepts, systems, devices, structures, and techniques sought to be protected are described above with reference to the related drawings. Alternative embodiments can be devised without departing from the scope of the concepts, systems, devices, structures, and techniques described.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities (things, components, items) can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more,” and “at least one” indicate any integer number greater than or equal to one, i.e., one, two, three, four, etc. Those terms, however, may refer to fractional numbers/values greater than one where context admits, e.g., “one or more” windings or “at least one” windings can refer to a number of windings of a coil having a fractional value such as 1.5, 2.75, 3.8, 6.6, etc. The term “plurality” indicates any integer number/value greater than one; that term, however, may refer to fractional numbers/values greater than one where context admits, e.g., a number of windings of a coil may be a plurality of windings having a fractional value, e.g., 1.7, 2, 2.3, 4, 5.6, etc. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A transformer-based integrated circuit (IC) package comprising:
a magnetic core including a soft ferromagnetic material;
a first substrate having a first plurality of conductive traces including first and second galvanically separate groups, wherein the first substrate includes a first receiving surface configured to receive the magnetic core; and
a second substrate having a second plurality of conductive traces including first and second galvanically separate groups, wherein the second substrate includes a second receiving surface configured to receive the magnetic core;
wherein the first and second galvanically separate groups of the first plurality of conductive traces is connected to the first and second galvanically separate groups of the second plurality of conductive traces at a plurality of connections, forming first and second coils galvanically separate coils disposed about the magnetic core, wherein the first and second coils and magnetic core are configured as a transformer.

2. The IC package of claim 1, further comprising an encapsulant configured to encapsulate the first substrate, wherein the encapsulant defines one or more surfaces of a package body.

3. The IC package of claim 1, wherein the first receiving surface and second receiving surface provide a space between the first and second substrates and an exterior surface of the magnetic core.

4. The IC package of claim 3, wherein the space comprises a gap between about 250 nm to about 2 mm.

5. The IC package of claim 1, further comprising at least one semiconductor die disposed on the first substrate and/or second substrate.

6. The IC package of claim 5, wherein the at least one semiconductor die comprises an integrated circuit (IC).

7. The IC package of claim 6, wherein the IC comprises a gate driver.

8. The IC package of claim 7, wherein the first and second coils are configured as primary and secondary coils in a step-up configuration, and wherein the gate driver is connected to the secondary coil.

9. The IC package of claim 1, wherein the magnetic core comprises ferrite.

10. The IC package of claim 1, wherein the first substrate and/or second substrate comprises a printed circuit board (PCB).

11. The IC package of claim 1, wherein the first substrate and/or second substrate comprises a glass substrate.

12. The IC package of claim 1, wherein the first substrate and/or second substrate comprises a ceramic substrate.

13. The IC package of claim 1, further comprising underfill material disposed between the first substrate and second substrate.

14. The IC package of claim 13, further comprising an injection port disposed in the first or second substrate and configured to allow injection of underfill into one or more regions between the first substrate and the second substrate.

15. The IC package of claim 13, wherein the underfill comprises encapsulation material.

16. The IC package of claim 13, wherein the underfill comprises epoxy.

17. A method of making an integrated circuit (IC) and transformer package, the method comprising:
providing a magnetic core including soft ferromagnetic material;
providing a first substrate having a first plurality of conductive traces including first and second galvanically separate groups, wherein the first substrate includes a first receiving surface for receiving a first portion of the magnetic core;
providing a second substrate having a second plurality of conductive traces including first and second galvanically separate groups, wherein the second substrate includes a second surface for receiving a second portion of the magnetic core;
positioning the magnetic core between the first and second receiving surfaces; and
joining the first plurality of conductive traces with the second plurality of conductive traces, thereby forming primary and secondary transformer coils configured about the magnetic core.

18. The method of claim 17, further comprising providing one or more IC die to the first or second substrate, wherein the one or more IC die are connected to at least a subset of the first plurality of conductive traces or second plurality of conductive traces.

19. The method of claim 17, further comprising providing an encapsulant to the first or second substrates, the encapsulant defining one or more surfaces of a package body.

20. The method of claim 17, wherein the first receiving surface and second receiving surface provide a space between the first and second substrates and an exterior surface of the magnetic core.

21. The method of claim 17, further comprising providing at least one semiconductor die disposed on the first substrate and/or second substrate.

22. The method of claim 21, wherein the at least one semiconductor die comprises an integrated circuit (IC).

23. The method of claim 22, wherein the IC comprises a gate driver.

24. The method of claim 17, wherein primary and secondary coils are configured in a step-up configuration.

25. The method of claim 17, wherein the magnetic core comprises ferrite.

26. The method of claim 17, wherein the first substrate and/or second substrate comprises a printed circuit board (PCB).

27. The method of claim 17, wherein the first substrate and/or second substrate comprises a glass substrate.

28. The method of claim 17, wherein the first substrate and/or second substrate comprises a ceramic substrate.

29. The method of claim 17, further comprising providing underfill material disposed between the first substrate and second substrate.

30. The method of claim 17, further comprising providing an injection port disposed in the first or second substrate and configured to allow injection of underfill into a region between the first substrate and second substrate.
